(19) United States
(12) Patent Application Publication
(10) Pub. No.: US 2008/0241711 A1
(43) Pub. Date: Oct. 2, 2008

(54) Removal and prevention of photo-induced defects on photomasks used in photolithography

(76) Inventors: Henry K. Yun, Santa Clara, CA (US); Archita Sengupta, San Jose, CA (US); Florence Eschbach, Portola Valley, CA (US)

Correspondence Address: INTEL/BSTZ;BLAKELY SOKOLOFF TAYLOR & ZAFMAN LLP, 1279 OAKMEAD PARKWAY, SUNNYVALE, CA, 94085-4040, US

(21) Appl. No.: 11/731,264

(22) Filed: Mar. 30, 2007

(51) Int. Cl. G03F 1/00

(52) U.S. Cl. 430/5; 134/104.2

(57) ABSTRACT

Photoinduced defects that occur on photomasks used in photolithography may be removed or prevented. In one example a photomask is installed into a vacuum chamber, the contaminants on the photomask are broken down with heat, illumination or both and the broken-down contaminants are removed with a vacuum.

### FIELD

The present description relates to cleaning photomasks (optical and EUV) that are used in photolithography for semiconductor, microelectronic and micro-machine devices and, in particular, to applying conditions to break down and remove foreign materials or defects from the mask surface in a vacuum chamber.

### BACKGROUND

Photolithography or lithography is used in the fabrication of semiconductor devices. In lithography, a light sensitive material, called a “photoresist”, coats the wafer substrate. When light is transmitted through the mask, the image on the mask is transferred to the photoresist. During this illumination process, the photoresist undergoes chemical reactions. The photoresist is then developed to produce a replicated pattern of the mask on the wafer. The mask and the wafer are typically enclosed inside a special chamber into which the light is projected. The lithography chamber is environmentally controlled for temperature, humidity, air flow, airborne molecular contamination (AMC), vibration and materials to reduce process variations.

The mask is typically made from a transparent substrate, such as glass or quartz (with or without antireflective and other metallic coatings, such as Chromium Oxide, Chromium Oxinitride, Molybdenum Silicide etc.) that is patterned with the features that are to be printed onto the wafer. The mask may be categorized as having two surfaces, the glass side or back side of the mask, and the front side of the mask where the pattern resides. On an optical mask, the patterns are typically made of Chromium Oxide coated with Chromium Oxinitride or Molybdenum Silicide. For an EUV (Extreme Ultraviolet) mask, the top surface may contain Mo—Si multilayers with Ruthenium/Tantalum-Oxinitride or some other combination of metallic coatings. On the front side of the optical mask, a pellicle is attached to protect the surface from foreign particles being deposited or added to the mask surface during usage and from storage and handling. An EUV mask, on the other hand, does not have a pellicle, due to the pellicle's absorption of the EUV light. Some other UV (Ultraviolet) and DUV (Deep Ultraviolet) processes may also be performed without using a pellicle.

In, for example, 193 nm (DUV) optical lithography using an ArF Excimer laser during photolithographic exposure, the laser light is directed to the back side of the photomask and passes through the front side of the mask and through the pellicle membrane to expose the wafer. During the exposure, the photolithography process may induce organic, inorganic and inorganic-organic hybrid defects (photo-induced), particles and impurities to be formed by photochemical reaction on the front and back side of the mask surface. These impurities or foreign particles may be formed on Quartz and Chromium Oxinitride and Molybdenum Silicide parts of the mask, among others. These defects or defect seeds may also form on the mask after photolithographic exposure while a mask is in a prolonged storage period under certain conditions. The defects or seeds can grow into larger crystals during later photolithographic exposure.

The reactions that form such defects may be triggered by chemical reactions of the accumulated seeds of ionic or molecular species present on the surface. Reactions may also be a result of adsorbed ionic and molecular outgassed and air-born species from various sources that accumulate over time. The species may come from the mask substrate making processes, mask fabrication and cleaning processes, pellicle materials (for example. mask adhesive and membrane adhesive and the pellicle frame) used on the mask, pellicle and mask transport, packaging and storage materials and conditions used in the mask shop or wafer factory, and other environments.

Inorganic residues, such as ammonium sulfate, ammonium carbamate or inorganic organic hybrid salts such as ammonium oxalate and ammonium formate may accumulate due to mask cleaning treatments using H₂SO₄/H₂O₂, carbonated water, and NH₄OH/H₂O₂ solutions and from materials leaching or outgassing during shipping and storage. Reactants from the sources, products or byproducts described above can react further to form various different complex compounds which can get nucleated, deposited, or adsorbed onto the mask surface. Similar or different conditions may be responsible for formation of organic, inorganic and inorganic-organic hybrid defects, particles, and impurities on the photomask used for DUV (248 nm), immersion 193 nm lithography and EUV lithography processes. Growth of these crystalline and non-crystalline defects (organic, inorganic and inorganic-organic hybrid particulates or impurities) can be extremely fast and may result in transmission loss and degradation of performance in the photolithographic process.

Therefore, the impact of these progressive photo-induced defects on a photomask can have a devastating impact on the wafer yield. The defects interfere with the patterning of the wafer and cause repeated bad die (RBD) with defects on the wafer itself.

Once photo-induced defects have been detected, a standard procedure is to remove the mask from the lithography chamber, remove the pellicle holding the photomask and subject the mask to cleaning in order to remove the accumulated defects. The cleaning process typically uses wet chemicals that chemically strip impurities off the mask. This process is sometimes referred to as repelliclization.

Removing the pellicle, cleaning the mask and replacing the pellicle is expensive, time consuming, and causes gradual degradation of the photomask in terms of phase loss and surface degradation due to the extensive use of corrosive chemicals and hot water. After some number of cleaning cycles, the photomask will eventually become unusable. The expense and delay may be still greater when the photomask shop that cleans the mask is not located in or near the wafer factory. In addition, the photomask may be damaged by the cleaning process. The optical properties of, for example, EPSM (Embedded Phase Shift Mask) photomasks and the patterned features can both be impacted by the cleaning process. This may cause the photomask to be damaged so much that it cannot be used.

### BRIEF DESCRIPTION OF THE DRAWINGS

Embodiments of the present invention may be understood more fully from the detailed description given below and from the accompanying drawings of various embodiments of the invention. The drawings, however, should not be taken to be limiting, but are for explanation and understanding only.

FIG. 1 is a diagram of an example of a semiconductor fabrication device suitable for application to the present invention;

FIG. 2 is a diagram of an example of a photomask and pellicle suitable for application to the present invention;

FIG. 3 is a diagram of an example of a cleaning chamber for photomasks suitable for application to the present invention;

FIG. 4 is a list of operations for cleaning a photomask according to an embodiment of the invention;

FIG. 5 is a list of operations for cleaning a photomask according to another embodiment of the invention; and

FIG. 6 is list of operations for cleaning a photomask according to another embodiment of the invention.

### DETAILED DESCRIPTION

Defects on the front and back side of a photomask, whether pelliclized or not, may be cleaned with a combination of illumination, heat, and vacuum. The illumination may be, for example, from a 193 nm ArF laser, a solid state pulsed laser, a flood lamp, or an electron beam (e-beam) that is assisted by a high to ultrahigh vacuum and controlled temperature conditions.

An oxidative gas may also be used to oxidize impurities. For example, air, which can generate oxygen radicals and reactive hydroxyl radicals (from moisture), when exposed to the illumination, or additional Ozone gas may be used to oxidize impurities before the vacuum is used. This can cause organic impurities to reach a final oxidation state of CO₂ and water vapor. These types of conditions can be produced using a special cleaning module built for the purpose or adapted from other processing equipment for an in-line post lithography periodic cleaning process. This process may be used to clean an optical (193 nm, 248 nm) or a EUV photomask surface. Such equipment is typically already available in a photolithography fabrication plant, so that the masks may be cleaned without being transported to another facility.

The particular wavelength of light for the cleaning exposure may be adapted to suit the particular application. The exposure may also be combined with the vacuum and temperature conditions as mentioned above. As an example, for certain inorganic defects 193 nm or other suitable wavelengths of laser or lamp exposure will help bring out the embedded ionic seeds (for example, ammonium and sulfate ions) on to the surface, which can then be removed by subsequent heat and vacuum treatment. Some of these defects also get evaporated under e-beam exposure. Any evaporated contaminants can be removed by a vacuum system.

The cleaning may be performed while the photomask is still pelliclized in an appropriate chamber. The high temperature combined with laser illumination (or e-beam exposure) under various atmospheric conditions including low to high to ultrahigh vacuum promotes photochemical decomposition, fragmentation reaction and thermal reaction, thermal oxidation, sublimation, and outgassing of organic, inorganic and organic-inorganic hybrid mixture compounds that have formed on the photomask. The fragmented, gaseous, and vaporous byproducts may then be desorbed from the surface and removed by the use of vacuum conditions. The vacuum thereby prevents the gases, vapors, or small fragments from potentially adsorbing back onto the photomask substrate or chrome patterns. The adsorbed species of molecules and ions may act as new nucleation sites for new defects to be formed when the photomask is put back into service. Cleaning the photomask with temperature controls and illumination extends the useful life of the photomask or reticle in the wafer factory or mask shop and postpones the need for re-cleaning and repelliclization.

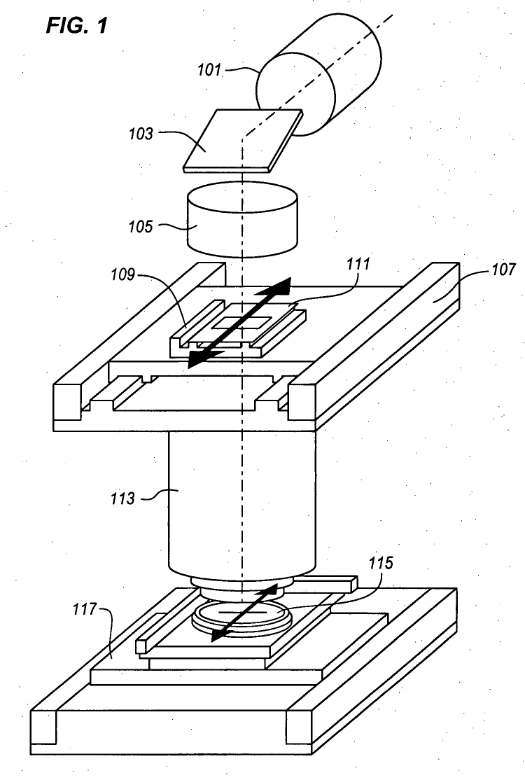

FIG. 1 shows an example of a conventional semiconductor fabrication machine, in this case, a ArF Excimer Laser Stepper or Scanner that may be used to hold a mask or produce a wafer in accordance with embodiments of the present invention. The stepper may be enclosed in a sealed vacuum chamber (not shown) in which the pressure, temperature and environment may be precisely controlled. The stepper has an illumination system including a light source 101, such as an ArF excimer laser, a scanning mirror 103, and a lens system 105 to focus the laser light on the wafer. A reticle scanning stage 107 carries a reticle holder 109 which holds the mask 111. The light from the laser is transmitted onto the mask and the light transmitted through the mask is focused further by a projection optics system 113 with, for example, a four-fold reduction of the mask pattern onto the wafer 115.

The wafer is mounted to a wafer scanning stage 117. The reticle scanning stage and the wafer scanning stage are synchronized to move the reticle and the wafer together across the field of view of the laser. In one example, the reticle and wafer move across the laser light in a thin line, then the laser steps down and the reticle and wafer move across the laser in another thin line until the entire surface of the reticle and wafer have been exposed to the laser. Such a step and repeat scanning system allows a high intensity narrow and coherent beam light source to illuminate the entire surface of the wafer. The stepper is controlled by a station controller (not shown) which may control the starting, stopping and speed of the stepper as well as the temperature, pressure and chemical makeup of the ambient environment, among other factors. The stepper of FIG. 1 is an example of how a mask and pellicle may be used. Embodiments of the invention may be applied to masks used in this type of photolithography and to many other photolithography systems.

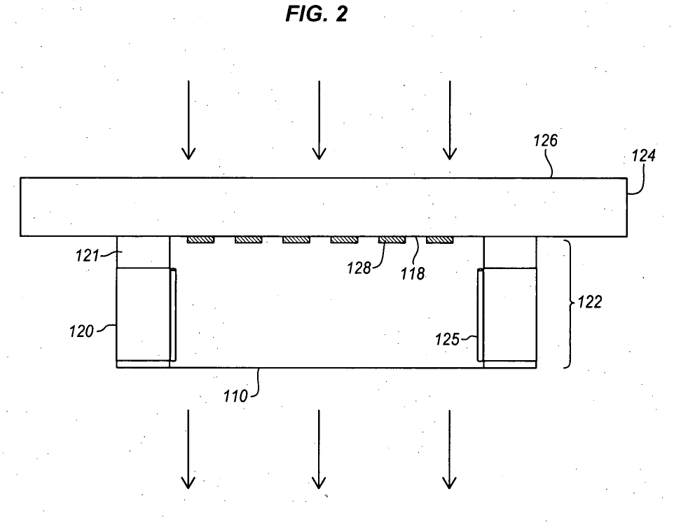

FIG. 2 shows a cross-section of an example of a pelliclized-mask assembly 110 suitable for use in the laser stepper of FIG. 1 as well as in other types of lithography equipment. The frame 120 of the PF (Pellicle-Frame) assembly 122 is shown in contact with a reticle or photomask 124. A tacky agent 125 on the inside of the frame serves to attract and trap particles that enter the interior of the frame. The tacky agent may also serve as a source of outgassed contaminants. The pattern material, such as chrome (CrOxN/CrO) lines 128 is on the front side 118 of the reticle 124 facing the pellicle membrane 110. For scale, in a typical semiconductor lithographic process, the photomask substrate is about 6″×6″×0.25″ (150 mm×150 mm×6.5 mm). For 193 nm lithography, the pattern 128 has a thickness of approximately 100 nm, but the particular nature of the patterning and its composition may depend on the application. The pattern is shown for illustration purposes and not to scale. A real pattern may be composed of many elements too small to be distinguishable in the drawings. The mask substrate is made of quartz and the back side 126 is typically a quartz surface.

As shown in the picture, the pellicle-frame assembly is attached to the front side of the mask using mask adhesive 121. The back side of the mask 126, opposite the front side and the pattern, is open to the ambient environment. In this description, any reference to the pellicle may be interpreted to include the whole pellicle assembly including the frame as shown in FIG. 2 or any one part of the pellicle assembly. The pellicle frame also usually has a PRV (pressure release valve not shown) which may be in the form of a small hole with gore patch filter or it may be more complex. A pellicle may also have multiple PRV holes (on opposite sides) to adjust pressure inside the active area. Arrows are shown to indicate the direction of illumination during photolithography. Light from the laser, as shown in FIG. 2, will be transmitted through the back of the photomask (through the quartz side for an optical photomask) and then through the patterned front side, through the pellicle, through the projection optics system and then illuminate the wafer. The wafer is below the pellicle as shown in FIG. 2.

The pelliclized active area on the front side of the mask may be one of the most reactive zones for chemical species to react; but eventually photo-induced defects may develop inside or outside the pelliclized area of the photomask. For an optical mask, defects can grow in the active area of the mask, the Molybdenum silicide area (shifter) of the phase shift mask, the clear (quartz area of the front side) of the mask, and the quartz back side of the mask. Sometimes defects may shift onto the inner side of the pellicle due to the handling of the mask.

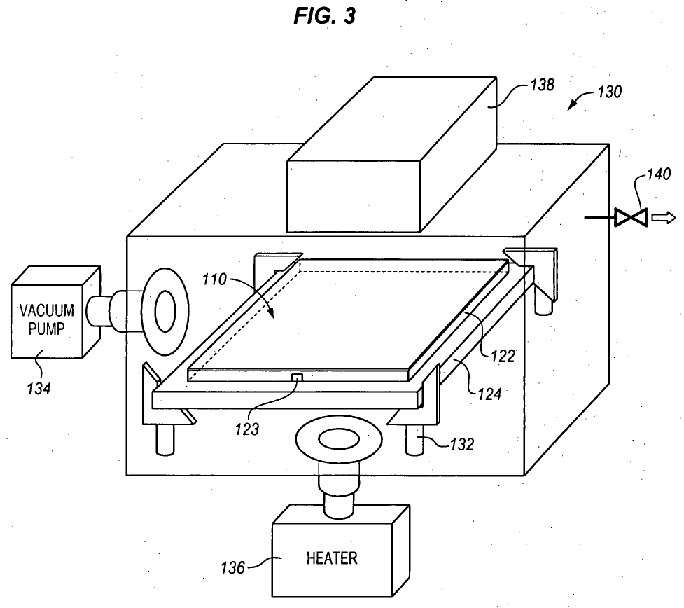

FIG. 3 shows an example of a specialized cleaning chamber 130 for removing photo-induced defects from a mask 124. Such a cleaning chamber may be provided as an additional module in a wafer fabrication facility placed adjacent or near photolithography equipment. By using a separate module for cleaning, the cleaning process may be done conveniently and immediately without affecting wafer processing in the photolithography equipment. A mask, after it is removed from the stepper or from storage, may be installed into a cleaning chamber, such as that of FIG. 3. After cleaning followed by inspection, it may then be moved back into the stepper or into storage to await its next use. Since defects may grow in use and in storage, it may be valuable to clean the mask both before being put into storage and after being removed from storage. By cleaning the mask before storage the seriousness of any defects that grow in storage will be reduced.

The cleaning chamber 130 has a mask support fixture 132 to support a photomask 124 while it is still protected by a pellicle 110 and frame 122. This support system may be vertically or horizontally placed inside the chamber. The pelliclized mask or a mask without a pellicle, depending on the application, may be placed into the fixture either face up or down for direct illumination of the front and back sides of the mask with a specific laser, lamp system, or e-beam system. The cleaning chamber includes a gas inlet 140 to introduce air or oxidative gas (such as ozone), that may be used to produce reactive oxygen radicals or hydroxyl radicals or both under a suitable light source, such as 193 nm laser light. The cleaning chamber includes a vacuum pump 134 to evacuate ambient air, oxidative gases, sublimated gases, and any other debris or fragmented materials in the chamber, which can operate up to high to ultra high vacuum conditions. Note that one or more PRV holes 123 (only one is shown, others may be on opposite sides) in the pellicle frame 122 help equilibrate the pressure and protects the pellicle from any damage due to changes in vacuum pressure. A heater 136 or temperature control unit allows the temperature in the chamber to be precisely controlled and the relief valve at inlet 140 allows the vacuum to be released and allows other oases or ambient air to be introduced into the chamber as desired. A light source 138, such as the 193 nm laser mentioned above, may be positioned inside or outside of the chamber to illuminate the mask as described in more detail below.

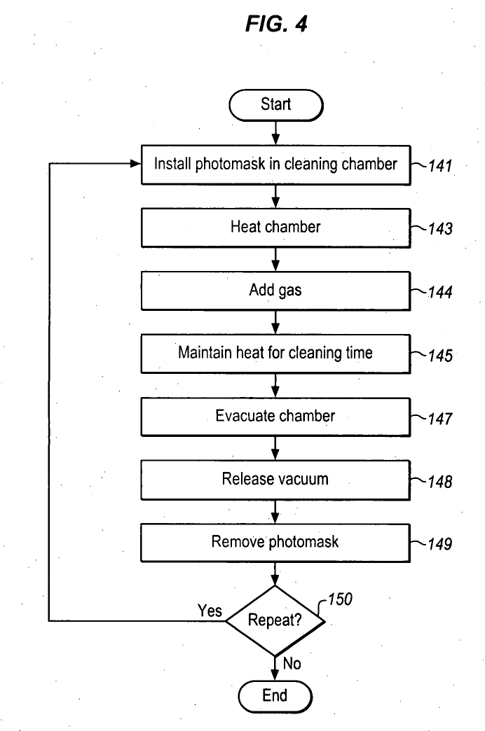

The photomask 124 in FIG. 3 is shown as still pelliclized Performing in-situ cleaning of a pelliclized photomask is quicker and safer than using time consuming and possibly damaging wet chemical processes that require removing and replacing the pellicle. This allows the cleaning to be performed quickly and without any risk of damage to the photomask. However, it may be preferred under certain circumstances to remove the pellicle and clean the mask without this protection. This may, for example, allow the cleaning processes of FIG. 4, 5, or 6 to be combined with wet chemical or other cleaning approaches if needed.

Occasionally, a pellicle is damaged or destroyed. The pellicle must be replaced before the mask can be used in some steppers. In such a situation, the photomask may be cleaned before or after a damaged pellicle is replaced. The cleaning process described in this patent may also be used after the damaged pellicle is removed and before a new pellicle is installed. Because the cleaning chamber can hold a photomask substrate unpelliclized or pelliclized, both front and back side up, photomasks may be cleaned under a variety of different circumstances and conditions.

The equipment shown in FIG. 3 may be similar to or the same as that used by many other process chambers that may be present in a semiconductor or microelectronic fabrication facility. An existing processing chamber may also be used for cleaning or a cleaning chamber may be built using existing parts or constructed specifically for use as a cleaning chamber. For example, a redesigned laser stepper of the type shown in FIG. 1 may be used. The scanning stages, projection and collection optics and many other components are not necessary to accomplish the cleaning described herein.

Considering the cleaning approach in more detail, the mask is first installed in a cleaning chamber 130, or any other suitable vacuum chamber. This is indicated in FIG. 4 as block 141. The front 118 or back side 126 of the photomask may be exposed, depending on the particular application. The chamber can hold such a standard substrate unpelliclized or pelliclized.

In one example, the chamber then may be exposed to a suitable light source or e-beam source while the chamber is filled with a particular gas or with air. The exposure under controlled environmental conditions and heating, as appropriate, will help decompose the defects and impurities into fragmented by-products and volatile components by either photochemical reactions or thermal reactions or combinations of both. In the example of FIG. 4, heating is used at block 143 and a gas such as moist air is introduced into the chamber at block 144. The most effective temperatures are as high as possible without damaging the pellicle 110. The best temperature for a particular application will depend upon the particular contaminants, illumination, gases and other aspects of the process.

After a period of time sufficient for the reactions to take place, indicated as block 145, the chamber is driven to a vacuum condition as shown in block 147. A low to ultra high vacuum may be used. For example a vacuum of 10⁻³ Torr (one thousandth of a Torr) may be sufficient. However, higher vacuums as high as 10⁻⁹ Torr (one billionth of a Torr) or lower may provide better results under certain conditions. As mentioned above, the vacuum pump evacuates the chamber and helps remove the fragmented, sublimable, or gaseous contaminants from the chamber, taking them away from the photomask. When the contaminants have been sufficiently removed, the vacuum is released at block 148 and ambient air, nitrogen or any other desired gas is added to the chamber for the chamber to reach standard pressure. The photomask may then be removed for storage or reinstallation in the stepper at block 149. If the cleaning process is being performed with the mask in the stepper, then the mask may be left in place to begin the next photolithography operation.

This cycle of exposure under a controlled environment, heating and vacuum may need to be repeated, as indicated at block 150, to obtain the best cleaning results. The repeated cleaning may be performed after the mask is removed and inspected or checked, as indicated by FIG. 4, or a standard process may be implemented in which the cleaning cycle is always repeated some number of times before the mask is inspected or checked. The best number of repetitions will depend upon the frequency of the cleaning, the type of mask, and the type of photolithography process. If the cleaning cycle is to be repeated without removing the mask, then the operation of releasing the vacuum 148 in one cycle may be combined with the operation of adding gas 144 in the next cycle.

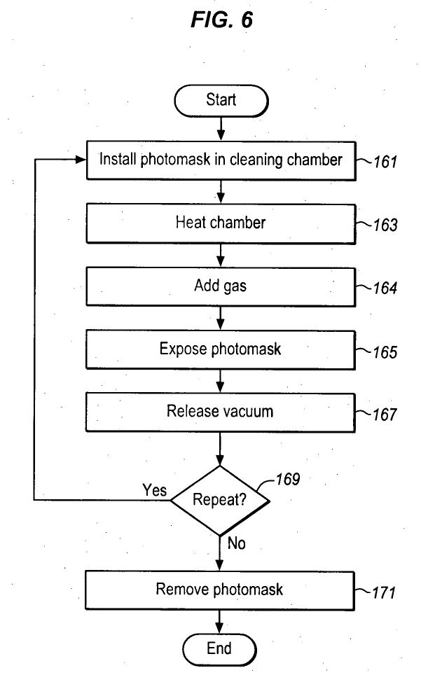

The heating may be started while the vacuum is being produced or it may be done before or after the vacuum is produced. In other words, the order of operations 143 and 147 may be reversed or the operations may be performed simultaneously. A temperature of about 120° C. has been found to work well without unduly stressing the photomask and pellicle. Higher temperatures may help sublimation of certain contaminants and may be selected depending on the nature of the contaminants and constituents of the photomask, keeping pellicle membrane integrity in mind. Masks without pellicles may be subjected to even higher temperatures. E-beam exposure followed by a vacuum treatment may work well for masks without pellicles to evaporate and remove some types of defects. Lower temperatures may also be used. For lower temperatures, adding illumination as shown in FIG. 6 is particularly beneficial. Room temperature heating of about 20° C. may be effective in removing some deposits and does not risk damaging the pellicle.

The heat operates to break down the photo-induced defects into small molecular fragments or to form sublimable or vaporous byproducts and the vacuum draws them out of the chamber. The defects are typically composed of molecules that may eventually form small fragments or sublimable or gaseous by-products in the presence of heat or upon exposure to certain wavelengths of light or both. The heating may be applied for durations of from a few minutes to a few hours depending on the temperature being used and other considerations.

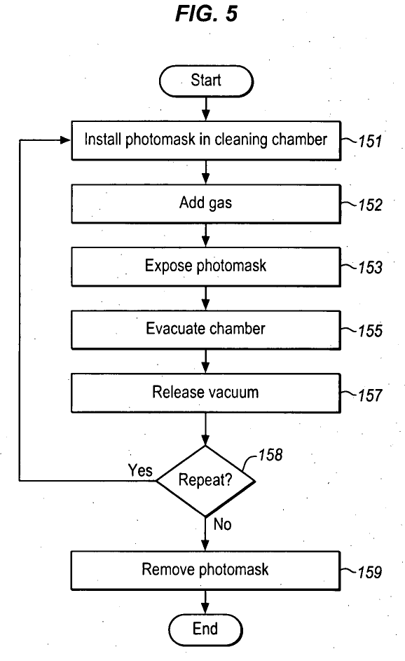

As may be understood further from the examples of FIGS. 5 and 6 there are several basic operations that may be put in different combinations and in different orders.

These Basic operations are:

1) Mask placement in a chamber (with or without pellicle, front or back side facing direct exposure).

2) Exposure (pulsed laser or pulsed lamp source of suitable wavelength such as 193 nm, or 248 nm or e-beam source).

3) Introduction of air or oxidative gas or reactants in the chamber.

4) Heating the mask in the chamber.

5) Allowing time for the measures of 2, 3, and 4 to operate.

6) After a certain period of reaction time, vacuum turn-on and a slow pump down to evacuate reaction fragments without impacting the pellicle, if present.

7) Releasing the vacuum and shutting off the illumination.

8) Repetitions until the desired results are achieved. The cleaning process may be performed with either heat or illumination or both. With both heat and illumination, the oxidative gas tends to promote the break-down of the contaminants, so either heat or illumination or both may be combined with exposure to the oxidative gas. Alternatively, no gas or an inert gas may be used. The primary reaction, as explained in more detail below, is to convert the contaminants into gases. This allows them to be drawn away by the vacuum pump. As mentioned above, depending upon the design of the pellicle and the nature of the gases, they may also be flushed out using another gas that is inert to the gases that are to be flushed out.

The entire photomask may be illuminated or the illumination may be limited to the areas in which the defects are located. A pulsed optical system may be provided that spreads a coherent adjustable high energy light source over the entire photomask. Since light transmission through the pellicle is higher than 99%, the active areas inside the pellicle may be cleaned without removing the pellicle. The best illumination source for a particular application will depend upon the particular defects and the oxidative gases that are to be used. While 193 nm exposure works well, in other circumstances 248 nm, i-line, g-line, or e-beam exposure may provide better results or take advantage of equipment that is more readily available.

For a pelliclized mask, the PRV hole (or multiple PRV holes) may help ventilate the byproducts that are formed during the exposure.

Instead of a pulsed optical system, a scanning stage may be used to scan the light across the photomask so that the entire photomask is exposed in lines. Special optics may be designed for illuminating the mask, rather than focusing on a wafer, or the mask may be illuminated without any special optics. Alternatively an e-beam source of suitable energy may serve a similar purpose for a non-pelliclized mask.

In an example of 193 nm pulsed ArF exposure, the cleaning exposure dose may vary from a few J/cm² to a few thousand J/cm² depending on the conditions of the cleaning, the type of mask (for example, STR, CON, POLY, and Metal layers), and the chemical composition of the defects. The cleaning exposure dose may be greater or less than a typical exposure dose used in photolithography for a particular layer (e.g. STR photolithography exposure may deliver a greater dose than POLY layer).

FIG. 5 shows an example of using illumination to clean a mask. According to FIG. 5, the photomask is first installed in the chamber at block 151. As in FIG. 4, if the mask is to be cleaned in the photolithography chamber in which it is used, this operation may be omitted. A reaction gas is then added to the chamber at block 152. This is followed by exposing the photomask at block 153 using any of the illumination approaches mentioned above. After a suitable reaction time, the chamber is evacuated at block 155, meaning that a vacuum pump or similar type of device is applied. Alternatively, the chamber may be flushed with a gas that is inert to the reaction products in the chamber. As mentioned above, this will remove the reaction by-products. At block 157, the vacuum is released. By this time the exposure operation will be completed and the illumination will be shut off. The illumination may continue during the vacuum operation or may be ended before the vacuum operation is begun. The operations may be repeated at block 158, depending on the particular circumstances. If there have been enough repetitions or if the photomask inspections indicate it to be sufficiently clean, then the photomask may be removed at block 159. The photomask may then be installed in a stepper or placed in storage. The cleaning processes of FIGS. 4 and 5 may also be alternated. So, for example, after performing a first cleaning process as indicated in FIG. 4, rather than repeating the FIG. 4 process, the FIG. 5 process or the FIG. 6 process may be used, or vice versa. Varying the process may provide for the elimination of a wider range of defects.

Illumination and temperature may be combined into a single cleaning process as suggested by FIG. 6. In FIG. 6, the pelliclized or unpelliclized photomask is installed in the cleaning chamber at block 161. The chamber is heated at block 163 and the photomask is illuminated at block 165. As mentioned above, air or oxidative gas, for example, ozone may be added to the chamber at block 164. The chamber is pumped out by the vacuum pump at block 166. The heating and illumination may be applied simultaneously or separately with either the heating first or the illumination first. When the cleaning is completed, the vacuum is released at block 167. For each of FIGS. 4, 5, and 6 additional operational cycles may be performed at block 169 while the photomask is in the cleaning chamber. The photomask is removed at block 171. As in FIGS. 4 and 5, the photomask may be restored to a stepper or put into storage for its next use.

The approaches described above may be applied from time to time either at a wafer factory for in-situ processing or at another location to reduce the number of defects on a mask. The other location may be a mask shop, for example. Cleaning at regular intervals during photolithography may be used to control and manage production time and yields. Defects, including photo-induced defects may be cleaned with these approaches, including inorganic, organic, and inorganic-organic hybrid type photo-induced defects. These may be eliminated before they print at the wafer level and have an impact on wafer yield. The techniques may accordingly be used as preventative maintenance for the photomask in a wafer factory.

These approaches may also be used to extend the lifetime or service life of photomasks. Since pelliclized masks may be cleaned in line at a wafer fabrication facility, the photomask no longer needs to be repelliclized by standard wet clean processes that can damage the photomask (through EPSM phase loss, or pattern damage) rendering the photomask unusable. These approaches may also reduce the need for frequent photomask inspections in the wafer factory or at the mask shop, thereby reducing costs. As a result, costs are reduced and the wafer yield and productivity of the factory are increased.

Photo-induced defects that form within the pellicle space may be organic type, inorganic type and organic-inorganic hybrid salt types. Due to the chemical nature of these organic, inorganic and hybrid compounds, they will undergo photochemical or thermal degradation, decomposition, and disproportionation reactions under suitable wavelengths of UV (ultraviolet) laser or lamp exposure or e-beam exposure and deliver reaction products which can desorb and be removed when exposed to the vacuum environment of the chamber. The best conditions for a particular production environment, photomask, and pellicle type may be determined experimentally. The example conditions described above are provided only as an example.

For a 193 nm actinic process, some of the major contributors to PID (Photo-Induced Defects) and haze formation (contaminants on the back side of the mask) are the following:

1) Examples of inorganic residual ions from mask cleaning processes: Sulfate (SO₄⁻²), Carbonate (CO₃⁻²), Carbamate, and Ammonium (NH₄⁺).

2) Examples of residual ions and organic esters in parts of the pellicle materials, such as the pellicle frame: Sulfate, Nitrate (NO₃⁻¹), Formate, Acetate

3) Examples of organic contaminants from pellicle materials such as mask adhesives: organic aliphatic and aromatic unsaturated hydrocarbons, ketones, esters, fatty acids, substituted phenolic derivatives, acrylic based compounds and organic amines.

4) Examples of inorganic and organic residual ions and molecules in mask shipping and storage and pellicle shipping and storage materials: Sulfate, Acetate, Formate, Caprolactum

5) Examples of contamination from the environment of the mask shop and the wafer factory: SOₓ, moisture, Ammonia, and Amines.

6) Examples of airborne molecular contamination (AMC): both organic small molecules, such as Acetic Acid, Iso-Propyl Alcohol, Toluene, and Xylene and inorganic molecules, such as amines, and ammonia.

7) Mask Storage and transportation materials such as ESD (Electro-Static Discharge) bags, compacts, RSP-SMWF (ABS) may contribute many different compounds including aromatic molecules, phenolic molecules, long chain esters, fatty acids, and sulfates.

8) Mask fabrication and storage and wafer fabrication environmental compounds, such as elements in the air, moisture and photoresists.

9) In addition, all of these organic and/or inorganic materials can react with each other in the internal environment of the stepper, including the laser illumination and can undergo photochemical reaction and post-photochemical crystal growth under moisture or certain environmental conditions (e.g. in presence of ammonia, SOₓ or amines).

The above examples show a wide range of different possible reactions. There may be many other compounds and many other reactions. The reactions may include photochemical reactions through free radical formation (Oxygen and Hydroxyl) and Ozonolysis (O₃ generated from Oxygen or air under 193 nm light). There may be reactions of some of the above mentioned molecules or similar molecules that are present under the reaction condition with hydroxyl radicals (generated from moisture in the air under laser illumination) and with outgassed photoresist and solvent vapors present in the environment, with airborne molecular contaminants (AMC), and with inorganic ionic residues left on the mask from cleaning process to form hybrid salts.

Inorganic defects may be formed on the photomask due to photo-catalytic exposure of residual ions on the photomask. This photochemical effect may create ammonium sulfate, ammonium carbonate, ammonium carbamate, and similar compounds, which then kinetically grow into larger crystals with the help of moisture or other conditions (such as reacting with ammonia or amines in the environment) during storage.

Organic-inorganic hybrid salt formation may also be generated by the interaction of ionic residues, such as ammonium ions, with short chain organic fatty acids, such as formic, oxalic, and acetic acids or ester residues.

Broad and general examples of some of the organics cleaned by light and oxidation include:

A) Oxidative Ozonolysis of unsaturated hydrocarbons will generate fragmented carbonyl compounds that may get further oxidized to fatty acids or esters that can be removed under further e-beam exposure or by heat followed by a vacuum treatment.

B) Primary alcohols or polyhydroxy aldehydes and ketones may get oxidized to carbon dioxide and water by oxidative degradation.

C) Photolytic, hydrolytic or oxidative cleavage of unsaturated hydrocarbons results in smaller fragments and the formation of carbonyl compounds, which can further oxidize to acid and finally oxidize to carbon dioxide (CO₂) and water (H₂O).

D) Photolytic and hydrolytic decomposition of esters may generate free acid and amines or ammonia, which can be removed under vacuum. CO2 is the highest oxidation state of organic molecules and may be a result from many organic oxidative reactions.

E) Ozonolysis of alkene, such as trans-2-butene, will result in bimolecular ketonic products and eventually fragmented products and radicals such as HCHO, CH3CO′, OH′, CO2, H2O and CH4, which can be removed easily under vacuum.

F) Examples of organics cleaned by heat: low molecular weight, sublimable hydrocarbons, acids, ketonic compounds, and alcohols.

G) Examples of inorganic compounds cleaned by e-beam or heat followed by vacuum: ammonium carbonate, ammonium carbamate, ammonium sulfate. Thermal degradation of ammonium sulfate results in ammonia, sulfur dioxide and nitrogen or nitrogenous oxides and these gaseous byproducts, such as ammonia, sulfur dioxide, nitrogen, or nitrogenous oxides can be removed under vacuum.

H) Ammonium carbonate is a mixture of ammonium bicarbonate and carbamate: NH₄HCO₃/NH₄O₂CNH₂. This can be unstable when exposed to air and may be converted into ammonium bicarbonate. Ammonium bicarbonate ultimately ends up liberating ammonia and carbon dioxide. Under e-beam, light, heat, or moisture exposure. The decomposition products include ammonia, carbon monoxide, carbon dioxide, and nitrogenous oxides.

I) Ammonium formate or oxalate may also produce ammonia and nitrogenous oxides under similar exposure and heat conditions.

The example cleaning processes described above are provided only as examples. There may be other and different chemical processes that break down, convert to gas or otherwise eliminate photo-induced defects on a mask. The example above show how combinations of illumination, heat, and exposure to gases such as air, oxygen, and water vapor can partially or completely eliminate these compounds and reduce the amount of or completely eliminate a wide range of different types of photo-induced defects from a photomask surface. The particular combination of illumination, heat, vacuum and other parameters may be selected with the above examples in mind. Alternatively, the particular combination may be selected based on the parameters described above and then optimized using trial and error.

A lesser or more complex cleaning chamber, set of cleaning operations, photomask, and pellicle may be used than those shown and described herein. Therefore, the configurations may vary from implementation to implementation depending upon numerous factors, such as price constraints, performance requirements, technological improvements, or other circumstances. Embodiments of the invention may also be applied to other types of photolithography systems that use different materials and devices (e.g. EUV lithography) than those shown and described herein. While the description above refers primarily to 193 nm photolithography equipment and techniques, the invention is not so limited and may be applied to a wide range of other wavelengths and other process parameters. In addition, the invention may be applied to the production of semiconductors, microelectronics, micromachines and other devices that use photolithography technology.

In the description above, numerous specific details are set forth. However, it is understood that embodiments of the invention may be practiced without these specific details. For example, well-known equivalent materials may be substituted in place of those described herein, and similarly, well-known equivalent techniques may be substituted in place of the particular processing techniques disclosed. In addition, steps and operations may be removed or added to the operations described to improve results or add additional functions. In other instances, well-known circuits, structures and techniques have not been shown in detail to avoid obscuring the understanding of this description.

While the embodiments of the invention have been described in terms of several examples, those skilled in the art may recognize that the invention is not limited to the embodiments described, but may be practiced with modification and alteration within the spirit and scope of the appended claims. The description is thus to be regarded as illustrative instead of limiting.

What is claimed is:

1. A method comprising:
installing a photomask into a vacuum chamber;
breaking down contaminants of the photomask; and
removing the broken-down contaminants with a vacuum.

2. The method of claim 1 wherein breaking down contaminants comprises applying illumination to the photomask in the vacuum chamber.

3. The method of claim 2, further comprising adding an oxidative gas to the photomask during applying illumination.

4. The method of claim 2, wherein the photomask has a patterned front side and a back side and wherein applying illumination comprises applying illumination to the front side of the photomask.

5. The method of claim 2, wherein applying illumination comprises applying illumination having a wavelength at least as long as the illumination to which the photomask is exposed in use.

6. The method of claim 2, wherein applying illumination comprises applying e-beam illumination.

7. The method of claim 2, wherein applying illumination comprises applying suitable light energy to break down photoinduced defects, such as inorganic, organic and organic-inorganic hybrid defects from the front and back side of the photomask.

8. The method of claim 1, wherein breaking down contaminants comprises applying heat to the photomask.

9. The method of claim 2, wherein breaking down contaminants further comprises applying heat to the photomask.

10. The method of claim 8, wherein applying heat comprises applying heat to break down photoinduced defects, such as inorganic, organic and organic-inorganic hybrid defects from the front and back side of the photomask

11. The method of claim 8, further comprising adding an oxidative gas to the chamber during applying heat.

12. The method of claim 11, wherein the oxidative gas comprises moist air.

13. The method of claim 1, wherein installing the photomask comprises installing the photomask with a pellicle attached to the photomask.

14. An apparatus comprising:
a chamber;
a fixture for holding a photomask and a pellicle attached to the photomask inside the chamber;
a gas inlet
a desorption agent to remove contaminants from the photomask; and
a vacuum pump to evacuate the removed contaminants from the chamber through the gas inlet.

15. The apparatus of claim 14, wherein the desorption agent is a heater.

16. The apparatus of claim 14, wherein the desorption agent is an illumination source.

17. The apparatus of claim 16, wherein the illumination source is an excimer laser.

18. A method comprising:
heating a photomask used in photolithography to desorb contaminants from a photomask;
illuminating the photomask during the heating to further desorb the contaminants; and
flushing the desorbed contaminants away from the photomask.

19. The method of claim 18, wherein flushing comprises applying a vacuum.

20. The method of claim 18, further comprising applying an oxidative gas during the heating to induce oxidation reactions of the contaminants.
